(19) United States
(12) Patent Application Publication
(10) Pub. No.: US 2024/0117219 A1
(43) Pub. Date: Apr. 11, 2024

(54) POLISHING COMPOSITION

(71) Applicant: FUJIMI INCORPORATED, Aichi (JP)

(72) Inventors: Yasuaki ITO, Aichi (JP); Hiroyuki ODA, Aichi (JP); Yuichiro NAKAGAI, Aichi (JP); Shogaku IDE, Aichi (JP); Naoto NOGUCHI, Aichi (JP); Shinichiro TAKAMI, Aichi (JP)

(21) Appl. No.: 18/275,321

(22) PCT Filed: Feb. 2, 2022
(86) PCT No.: PCT/JP2022/004018

§ 371 Date: Aug. 1, 2023

(30) Foreign Application Priority Data
Feb. 4, 2021 (JP) 2021-016868

(51) Int. Cl. C09G 1/02; B24B 37/04

(52) U.S. Cl. CPC C09G 1/02; B24B 37/044; H01L 21/30625

(57) ABSTRACT

Provided is a polishing composition that can reduce increase in temperature of a polishing pad during polishing. The polishing composition provided by the present invention contains water, oxidant A selected from compounds other than peroxide, a first metal salt selected from alkaline-earth metal salts, and a second metal salt selected from salts each of which has a cation of a metal belonging to groups 3 to 16 in the periodic table, and an anion.

### TECHNICAL FIELD

The present invention relates to a polishing composition.

The application claims the priority based on Japanese Patent Application No. 2021-016868, filed on Feb. 4, 2021, the content of which is herein incorporated by reference in its entirety.

### BACKGROUND ART

A surface of a material such as metal, semimetal, non-metal, or an oxide thereof has been polished with a polishing composition. For example, a surface made of a compound semiconductor material, such as silicon carbide, boron carbide, tungsten carbide, silicon nitride, titanium nitride, or gallium nitride is processed by polishing (lapping), which is performed by supplying a diamond abrasive (abrasive particles) between the surface and a polishing platen. However, lapping with a diamond abrasive is prone to generate defects and strains due to generated or remaining scratches or dents, or the like. For this reason, exploration has been made for polishing with a polishing pad and a polishing composition, after lapping with a diamond abrasive or instead of such lapping. Examples of literatures disclosing this kind of conventional technique include Patent Literatures 1 and 2.

### CITATION LIST

### Patent Literature

[Patent Literature 1] WO2018/174008
[Patent Literature 2] WO2019/138846

### SUMMARY OF INVENTION

### Technical Problem

Generally, a polishing removal rate is required to be practically, sufficiently high in view of manufacturing efficiency, cost-effectiveness, and the like. For example, polishing of a surface made of a high hardness material such as silicon carbide has strongly required an improved polishing removal rate. Patent Literatures 1 and 2 have proposed that a polishing rate is improved by containing an alkali metal salt and/or an alkaline-earth metal salt as a polishing promoter in a polishing composition including water and an oxidant but no abrasive (Patent Literature 1) or including an abrasive (Patent Literature 2).

A polishing removal rate can be improved by setting of polishing conditions such as increasing a load on a surface to be polished in polishing to gain a processing pressure, or speeding up platen rotation of a polishing machine. However, a polishing composition applied with the art in Patent Literatures 1 or 2 tends to cause a higher increase in temperature of a polishing pad during polishing using the polishing composition. Reduction of increase in temperature of a polishing pad allows employing more severe processing conditions, thus bringing about benefit for further improving a polishing removal rate.

The present invention was made in light of such circumstances, and has an objective to provide a polishing composition that can reduce increase in temperature of a polishing pad during polishing. Another related object is to provide a polishing method of an object to be polished using such a polishing composition.

### Solution to Problem

The polishing composition provided herein contains water, oxidant A selected from compounds other than peroxides, a first metal salt selected from alkaline-earth metal salts, and a second metal salt selected from salts each of which has a cation of a metal belonging to groups 3 to 16 in the periodic table and an anion. This inclusion of a combination of the first metal salt and the second metal salt allows improving a polishing removal rate of a polishing composition containing water and oxidant A, and reducing increase in temperature of a polishing pad (hereinafter also referred to as pad temperature).

In some preferred embodiments of the art disclosed herein (encompassing polishing compositions, polishing methods, production methods of a polished object, etc., with the same applying hereinafter), oxidant A is permanganate. In a polishing composition containing permanganate as oxidant A, use of a combination of the first metal salt and the second metal salt allows improving a polishing removal rate as well as reducing increase in pad temperature effectively.

In some embodiments, the first metal salt is preferably nitrate. Combination of alkali-earth metal nitrate as the first metal salt with the second metal salt can preferably exert an effect to improve a polishing removal rate as well as to reduce increase in pad temperature.

In some embodiments, the second metal salt is preferably an aluminum salt. Combination of the first metal salt with an aluminum salt as the second metal salt can preferably exert an effect to improve a polishing removal rate as well as to reduce increase in pad temperature.

In some preferred embodiments, the first metal salt and the second metal salt have the same anion species. Combination of the first metal salt with the second metal salt selected so as to have the same anion species tends to better exert an effect to reduce increase in pad temperature.

In some embodiments, the ratio of the concentration of the second metal salt C2 [mM] to the concentration of the first metal salt C1 [mM] in the polishing composition (i.e., C2/C1) may be e.g., 0.1 to 10. Such composition can preferably exert an effect caused by use of a combination of the first metal salt and the second metal salt.

In some embodiments, the polishing composition further contains an abrasive (or abrasive particles. The same applies hereinafter.). Use of an abrasive can improve a polishing removal rate. Furthermore, since polishing with use of a polishing composition containing an abrasive tends to be accompanied by higher pad temperature relative to use of a polishing composition containing no abrasive, it is more effective to apply the art disclosed herein to reduce increase in pad temperature.

The polishing composition disclosed herein is used for, e.g., polishing a material having a Vickers hardness of 1500 Hv or more. In polishing of such a high hardness material, an effect caused by the art disclosed herein can be preferably exerted. In some embodiments, the material having a Vickers hardness of 1500 Hv or more is non-oxide (i.e., a compound that is not an oxide). Polishing of a non-oxide material to be polished is more likely to preferably exert an effect to improve a polishing removal rate by the polishing composition disclosed herein.

The polishing composition disclosed herein is used for, e.g., polishing of silicon carbide. In polishing of silicon carbide, an effect caused by the art disclosed herein can be preferably exerted.

The specification further provides a polishing method of an object to be polished. The polishing method includes a step of polishing an object to be polished using any of the polishing compositions disclosed herein. Such a polishing method can reduce increase in pad temperature as well as gain a polishing removal rate, even in polishing an object to be polished that is formed of a high hardness material. This can improve productivity of an object derived via polishing with the polishing method (a polished object, e.g., a compound semiconductor substrate such as a silicon carbide substrate).

### DESCRIPTION OF EMBODIMENTS

Preferred embodiments of the present invention will be described below. Matters that are other than those particularly mentioned herein but are necessary for implementation of the present invention can be recognized as matters to be designed by those skilled in the art based on conventional technologies in the art. The present invention can be implemented based on contents disclosed herein and common technical knowledge in the art.

### <Polishing Composition>

### (Oxidant A)

The polishing composition disclosed herein contains oxidant A selected from compounds other than peroxides. Oxidant A can exert an effect to improve a polishing removal rate in polishing of a material to be polished (e.g., a non-oxide material having high hardness such as silicon carbide). Specific examples of a compound to be a potential option of oxidant A include permanganate compounds including permanganic acid and salts thereof such as sodium permanganate and potassium permanganate; periodate compounds including periodic acid and salts thereof such as sodium periodate and potassium periodate; iodate compounds including iodic acid and salts thereof such as ammonium iodate; bromate compounds including bromic acid and salts thereof such as potassium bromate; ferrate compounds including ferric acid and salts thereof such as potassium ferrate; chromate compounds and dichromate compounds including chromic acid and salts thereof such as potassium chromate, and dichromic acid and salts thereof such as potassium dichromate; vanadate compounds including vanadic acid and salts thereof such as ammonium vanadate, sodium vanadate, and potassium vanadate; ruthenate compounds including perruthenic acid and salts thereof; molybdate compounds including molybdic acid and salts thereof such as ammonium molybdate and disodium molybdate; rhenate compounds including perrhenic acid and salts thereof; tungstate compounds including tungstic acid and salts thereof such as disodium tungstate; and chlorate compounds and perchlorates including chloric acid and salts thereof, and perchloric acid and salts thereof such as potassium perchlorate. Oxidant A can be used as a single kind or in combination of two or more kinds of such compounds. In some embodiments, oxidant A is preferably an inorganic compound in view of performance stability of the polishing composition (e.g., prevention of deterioration caused by long-term storage).

In some preferred embodiments, the polishing composition contains, as oxidant A, a composite metal oxide that is a salt of a cation selected from alkali metal ions and an anion selected from transition metal oxoacid ions. The composite metal oxide is effective e.g., to reduce hardness of a high hardness material such as silicon carbide and make the material fragile. A polishing composition containing the composite metal oxide as oxidant A can preferably exert effects to improve a polishing removal rate and to reduce increase in pad temperature, by combination use of the first metal salt and the second metal salt. The composite metal oxide can be used as a single one kind or in combination of two or more kinds thereof. Specific examples of the transition metal oxoacid ion in the composite transition metal oxide include permanganate ions, ferrate ions, chromate ions, dichromate ions, vanadate ions, ruthenate ions, molybdate ions, rhenate ions, and tungstate ions. In particular, more preferred is oxoacid of a period 4 transition metal in the periodic table. Preferred examples of the period 4 transition metal element in the periodic table include Fe, Mn, Cr, V and Ti. In particular, more preferred are Fe, Mn and Cr, and yet more preferred is Mn. An alkali metal ion in the composite transition metal oxide is preferably Na⁺ or K⁺. In some embodiments, potassium permanganate can be preferably employed as oxidant A.

When a compound used as oxidant A is salt (e.g., permanganate), the compound may be present in form of an ion in the polishing composition.

The polishing composition disclosed herein may or may not further contain an oxidant other than oxidant A. The art disclosed herein can be preferably implemented in an embodiment not substantially containing an oxidant (e.g., hydrogen peroxide) other than oxidant A.

The concentration (content) of oxidant A in the polishing composition is not particularly limited, and can be appropriately set corresponding to a purpose of use, an embodiment of use, etc. of the polishing composition. In some embodiments, in view of improving a polishing removal rate, the concentration of oxidant A is suitably approximately 5 mM or more (i.e., 0.005 mol/L or more). In view of improving a polishing removal rate, the concentration of oxidant A is preferably 10 mM or more, and more preferably 30 mM or more, and may be 50 mM or more, 70 mM or more, or 90 mM or more. In view of facilitating achieving a higher polishing removal rate, in some embodiments, the concentration of oxidant A may be 120 mM or more, 140 mM or more, or 160 mM or more. Additionally, in some embodiments, the concentration of oxidant A in the polishing composition is suitably approximately 2500 mM or less, preferably 2000 mM or less, and more preferably 1700 mM or less, and may be 1500 mM or less, 1000 mM or less, 750 mM or less, 500 mM or less, 400 mM or less, or 300 mM or less. Less concentration of oxide A can be advantageous in view of reducing increase in pad temperature. In such view, in some embodiments, the concentration of oxidant A may be 250 mM or less, 200 mM or less, 150 mM or less, or 120 mM or less.

### (First Metal Salt)

The polishing composition disclosed herein contains a first metal salt selected from alkaline-earth metal salts in addition to oxidant A. As the first metal salt, a single kind of alkaline-earth metal salt can be used, or two or more kinds of alkaline-earth metal salts can be used in combination. Use of a combination of the first metal salt and the second metal salt described later allows to effectively combine improvement in a polishing removal rate and reduction of increase in pad temperature. The first metal salt preferably contains any one kind or two or more kinds of Mg, Ca, Sr and Ba, as an element(s) belonging to alkaline-earth metals. In particular, either of Ca or Sr is preferable, and Ca is more preferable.

The kind of a salt in the first metal salt is not particularly limited, and may be an inorganic acid salt or an organic acid salt. Examples of the inorganic acid salt include salts of hydrohalic acid such as hydrochloric acid, hydrobromic acid, and hydrofluoric acid; nitric acid; sulfuric acid; carbonic acid; silicic acid; boric acid; and phosphoric acid. Examples of the organic acid salt include salts of carboxylic acids such as formic acid, acetic acid, propionic acid, benzoic acid, glycine acid, butyric acid, citric acid, tartaric acid, and trifluoroacetic acid; organic sulfonic acids such as methanesulfonic acid, trifluoromethanesulfonic acid, benzenesulfonic acid, and toluenesulfonic acid; organic phosphonic acids such as methylphosphonic acid, benzenephosphonic acid, and toluenephosphonic acid; and organic phosphoric acid such as ethylphosphoric acid. In particular, preferred are salts of hydrochloric acid, nitric acid, sulfuric acid, and phosphoric acid, and more preferred are salts of hydrochloric acid and nitric acid. The art disclosed herein can be preferably implemented e.g., in an embodiment with using a nitrate or chloride of an alkaline-earth metal as the first metal salt.

Specific examples of an alkaline-earth metal salt to be a potential option of the first metal salt include chlorides such as magnesium chloride, calcium chloride, strontium chloride, and barium chloride; bromides such as magnesium bromide, calcium bromide, strontium bromide, and barium bromide; fluorides such as magnesium fluoride, calcium fluoride, strontium fluoride, and barium fluoride; nitrates such as magnesium nitrate, calcium nitrate, strontium nitrate, and barium nitrate; sulfates such as magnesium sulfate, calcium sulfate, strontium sulfate, and barium sulfate; carbonates such as magnesium carbonate, calcium carbonate, strontium carbonate, and barium carbonate; carboxylates such as magnesium acetate, calcium acetate, strontium acetate, barium acetate, magnesium benzoate, calcium benzoate, barium benzoate, magnesium citrate, calcium citrate, strontium citrate, and barium citrate.

The first metal salt is preferably a water-soluble salt. Use of the first metal salt with water solubility can efficiently form a good surface with less defects such as a scratch.

The first metal salt is also preferably a compound different from oxidant A, as well as a compound not to be oxidized by oxidant A. In such view, appropriate selection of oxidant A and the first metal salt allows preventing deactivation of oxidant A due to oxidization of the first metal salt by the oxidant A, and reducing age-related deterioration of performance of the polishing composition (e.g., reduction in a polishing removal rate). One example of a preferable combination of oxidant A and the first metal salt is a combination of a permanganate alkali metal salt and calcium nitrate.

The concentration (content) of the first metal salt in the polishing composition is not particularly limited, and can be appropriately set so as to achieve a desired effect, corresponding to a purpose of use, an embodiment of use, etc. of the polishing composition. The concentration of the first metal salt may be, e.g., approximately 1000 mM or less, 500 mM or less, or 300 mM or less. In combination use with the second metal salt, in view of effectively combining improvement in a polishing removal rate and reduction of increase in pad temperature, the concentration of the first metal salt in some embodiments is suitably 200 mM or less, preferably 100 mM or less, and more preferably 50 mM or less, and may be 30 mM or less, 20 mM or less, or 10 mM or less. The lower limit of the concentration of the first metal salt may be, e.g., 0.1 mM or more, and in view of appropriately exerting an effect of use of the first metal salt, preferably 0.5 mM or more, and more preferably 1 mM or more, and may be 2.5 mM or more, or 5 mM or more. The art disclosed herein can be preferably implemented e.g., in an embodiment where the concentration of the first metal salt in the polishing composition is 0.5 mM to 100 mM, or 1 mM to 50 mM.

Without no particular limitation, in view of better exerting an effect caused by containing the first metal salt in the polishing composition containing oxidant A, the ratio of the concentration of the first metal salt (represented by the total concentration if containing a plurality of the first metal salts) C1 [mM] to the concentration of oxidant A (represented by the total concentration if containing a plurality of oxidants A) Cx [mM] in the polishing composition (C1/Cx) is suitably approximately 0.0002 or more, preferably 0.001 or more, and more preferably 0.005 or more, and may be 0.01 or more, or 0.02 or more. In some embodiments, C1/Cx may be e.g., 0.03 or more, 0.05 or more, or 0.07 or more. The upper limit of C1/Cx is not particularly limited, but is suitably roughly 200 or less, and may be 100 or less, 75 or less, or 50 or less. In some preferred embodiments, C1/Cx may be 20 or less, 10 or less, 5 or less, 1 or less, 0.5 or less, 0.3 or less, or 0.1 or less. Such a concentration ratio of the first metal salt to oxidant A (C1/Cx) can preferably provide improvement in a polishing removal rate and reduction of increase in pad temperature that are caused by combination use of the first metal salt and the second metal salt described later.

### (Second Metal Salt)

The polishing composition disclosed herein further contains a second metal salt in addition to oxidant A and the first metal salt. The second metal salt is selected from salts each of which has a cation of a metal belonging to groups 3 to 16 in the periodic table and an anion, and can be used as a single kind or in combination of two or more kinds. In composition containing oxidant A, use of a combination of the aforementioned first metal salt and the second metal salt can effectively combine improvement in a polishing removal rate and reduction of increase in pad temperature.

A cation of the second metal salt may be a cation of a transition metal, i.e., a metal belonging to groups 3 to 12 in the periodic table, or a cation of a poor metal, i.e., a metal belonging to groups 13 to 16. The transition metal is preferably a metal belonging to groups 4 to 10 in the periodic table, and also suitably a metal belonging to periods 4 to 6 in the periodic table, preferably a metal belonging to periods 4 to 5, and more preferably a metal belonging to period 4. The poor metal is preferably a metal belonging to groups 13 to 15 in the periodic table, more preferably a metal belonging to groups 13 to 14, and also preferably a metal belonging to periods 3 to 5 in the periodic table, more preferably a metal belonging to periods 3 to 4, and particularly preferably a poor metal belonging to period 3, i.e., aluminum.

In some embodiments, the second metal salt is preferably a salt of a cation of a metal exhibiting a pKa of approximately 10 or less in form of a hydrated metal ion, and an anion. The second metal salt that is a salt of such a cation and an anion tends to have high stability to oxidization, and thus facilitates reduction of age-related deterioration of performance of the polishing composition. In such view, the second metal salt to be potentially employed can be preferably a salt of a metal cation exhibiting a pKa of, e.g., 8.0 or less, 7.0 or less, or 6.0 or less in form of a hydrated metal ion, and an anion. Examples of the metal cation exhibiting a pKa of 6.0 or less in form of hydrated metal ion include, but are not limited to, Al³⁺ (exhibiting a pKa of 5.0 in form of a hydrated metal ion), Cr³⁺ (4.0), and Fe³⁺ (2.2).

The kind of a salt in the second metal salt is not particularly limited, and may be an inorganic acid salt or an organic acid salt. Examples of the inorganic acid salt include salts of hydrohalic acid such as hydrochloric acid, hydrobromic acid, and hydrofluoric acid; nitric acid; sulfuric acid; carbonic acid; silicic acid; boric acid; and phosphoric acid. Examples of the organic acid salt include salts of carboxylic acids such as formic acid, acetic acid, propionic acid, benzoic acid, glycine acid, butyric acid, citric acid, tartaric acid, and trifluoroacetic acid; organic sulfonic acids such as methanesulfonic acid, trifluoromethanesulfonic acid, benzenesulfonic acid, and toluenesulfonic acid; organic phosphonic acids such as methylphosphonic acid, benzenephosphonic acid, and toluenephosphonic acid; and organic phosphoric acid such as ethylphosphoric acid. In particular, preferred are salts of hydrochloric acid, nitric acid, sulfuric acid and phosphoric acid, and more preferred are salts of hydrochloric acid, nitric acid and sulfuric acid. The art disclosed herein can be preferably implemented in an embodiment e.g., with use of a salt of any cation of Al³⁺, Cr³⁺ or Fe³⁺, and a nitrate ion (NO₃⁻) or a chloride ion (Cl⁻), as the second metal salt.

The second metal salt is preferably a water-soluble salt. Use of the second metal salt with water solubility can efficiently form a good surface with less defects such as a scratch.

The second metal salt is also preferably a compound different from oxidant A, as well as a compound not to be oxidized by oxidant A. In such view, appropriate selection of oxidant A and the second metal salt allows preventing deactivation of oxidant A due to oxidization of the second metal salt by the oxidant A, and reducing age-related deterioration of performance of the polishing composition (e.g., reduction in a polishing removal rate). Examples of a preferable combination of oxidant A and the second metal salt include a combination of a permanganate alkali metal salt and aluminum nitrate, and a combination of a permanganate alkali metal salt and aluminum chloride.

In some preferred embodiments, the first metal salt and the second metal salt have the same anion species. Such combination of the first metal salt and the second metal salt can reduce more effectively increase in pad temperature. An anion species common in the first metal salt and the second metal salt may be, e.g., nitrate, hydrochloride, or phosphate. In view of providing higher effect, it is particularly preferable that both the first metal salt and the second metal salt contained in the polishing composition are nitrates.

The concentration (content) of the second metal salt in the polishing composition is not particularly limited, and can be appropriately set so as to achieve a desired effect, corresponding to a purpose of use, an embodiment of use, etc. of this polishing composition. The concentration of the second metal salt may be, e.g., approximately 1000 mM or less, 500 mM or less, or 300 mM or less. In combination use with the first metal salt, in view of effectively combining improvement in a polishing removal rate and reduction of increase in pad temperature, the concentration of the second metal salt in some embodiments is suitably 250 mM or less, preferably 200 mM or less, and more preferably 100 mM or less, and may be 50 mM or less, 30 mM or less, 20 mM or less, or 10 mM or less. The lower limit of the concentration of the second metal salt may be, e.g., 0.1 mM or more, and in view of appropriately exerting an effect of use of the second metal salt, advantageously 1 mM or more, preferably 5 mM or more, and more preferably 7 mM or more (e.g., 8 mM or more). The art disclosed herein can also be preferably implemented, e.g., in an embodiment where the concentration of the second metal salt in the polishing composition is 10 mM or more, 20 mM or more, or 30 mM or more.

The relation between the concentration of the first metal salt C1 [mM] and the concentration of the second metal salt C2 [mM] in the polishing composition is not particularly limited, and can be set so as to appropriately exert an effect caused by combination use thereof. For example, C1/C2 may fall within the range of 0.001 to 1000. In view of preferably combining improvement in a polishing removal rate and reduction of increase in pad temperature, C1/C2 in some embodiments is suitably approximately 0.005 or more, and preferably 0.01 or more (e.g., 0.025 or more). C1/C2 is also suitably approximately 100 or less, preferably 50 or less, and more preferably 25 or less (e.g., 10 or less).

Without no particular limitation, in view of better exerting an effect caused by using a combination of the first metal salt and the second metal salt in the polishing composition containing oxidant A, the ratio of the concentration of the second metal salt (represented by the total concentration if containing a plurality of the second metal salts) C2 [mM] to the concentration of oxidant A (represented by the total concentration if containing a plurality of oxidants A) Cx [mM] in the polishing composition (C2/Cx) is suitably approximately 0.0002 or more, preferably 0.001 or more, and more preferably 0.005 or more, and may be 0.01 or more, or 0.02 or more. In view of enhancing an effect to reduce increase in pad temperature, C2/Cx in some embodiments may be e.g., 0.03 or more, preferably 0.04 or more, or 0.05 or more, or 0.07 or more. The upper limit of C2/Cx is not particularly limited, but is suitably roughly 200 or less, and may be 100 or less, 75 or less, or 50 or less. In some preferred embodiments, C2/Cx may be 20 or less, 10 or less, 5 or less, 1 or less, 0.6 or less, 0.3 or less, or 0.2 or less. Such a concentration ratio of the second metal salt to oxidant A (C2/Cx) can preferably provide improvement in a polishing removal rate and reduction of increase in pad temperature that are caused by combination use of the first metal salt and the second metal salt described later.

### (Abrasive)

In some embodiments in the art disclosed herein, the polishing composition contains an abrasive (abrasive particles). The polishing composition containing an abrasive exerts mainly mechanical polishing action caused by the abrasive in addition to mainly chemical polishing action caused by oxidant A, the first metal salt and the second metal salt, and thereby can achieve a higher polishing removal rate. Since inclusion of the abrasive in the polishing composition also tends to result in increase in pad temperature, it is more effective to apply the art disclosed herein to reduce increase in pad temperature.

The material, properties, and the like of the abrasive are not particularly limited. For example, the abrasive may be any of inorganic particles, organic particles, and organic-inorganic composite particles. Examples thereof include an abrasive substantially formed of any of the following: oxide particles such as silica particles, alumina particles, cerium oxide particles, chromium oxide particles, titanium dioxide particles, zirconium oxide particles, magnesium oxide particles, manganese dioxide particles, zinc oxide particles, and iron oxide particles; nitride particles such as silicon nitride particles and boron nitride particles; carbide particles such as silicon carbide particles and boron carbide particles; diamond particles; and carbonates such as calcium carbonate and barium carbonate. The abrasive may be used as a single kind or in combination of two or more kinds thereof. In particular, preferred are oxide particles such as silica particles, alumina particles, cerium oxide particles, chromium oxide particles, zirconium oxide particles, manganese dioxide particles, and iron oxide particles, because of their ability to form a good surface. Specifically, more preferred are silica particles, alumina particles, zirconium oxide particles, chromium oxide particles, and iron oxide particles, and particularly preferred are silica particles and alumina particles. In an embodiment with use of silica particles or alumina particles as the abrasive, the art disclosed herein can be applied to preferably exert an effect to reduce increase in pad temperature.

Note that “substantially consisting of X” or “substantially formed of X” for composition of the abrasive herein means that the proportion of X in the abrasive (purity of X) is 90% or more by weight. The proportion of X in the abrasive is preferably 95% or more, more preferably 97% or more, even more preferably 98% or more, and e.g., 99% or more.

The average primary particle diameter of the abrasive is not particularly limited. In view of reducing increase in pad temperature as well as easily providing a desired polishing removal rate, the average primary particle diameter of the abrasive can be e.g., 5 nm or more, is suitably 10 nm or more, and preferably 20 nm or more, and may be 30 nm or more. In view of improving a polishing removal rate, the average primary particle diameter of the abrasive in some embodiments may be 50 nm or more, 80 nm or more, 150 nm or more, 250 nm or more, or 350 nm or more. Additionally, in view of reducing increase in pad temperature, the average primary particle diameter of the abrasive can be, e.g., 5 μm or less, preferably 3 μm or less, and more preferably 1 μm or less, and may be 750 nm or less, or 500 nm or less. In view of a surface quality after polishing, the average primary particle diameter of the abrasive in some embodiments may be 350 nm or less, 180 nm or less, 85 nm or less, or 50 nm or less.

The average primary particle diameter as used herein refers to a particle diameter (BET particle diameter) calculated from a specific surface area measured by a BET method (BET value) by the formula: average primary particle diameter (nm)=6000/(true density (g/cm³)×BET value (m²/g)). The specific surface area can be measured using e.g., a surface area measurement device with the product name of “Flow Sorb II 2300”, manufactured by Micromeritics Instrument Corporation.

The average secondary particle diameter of the abrasive may be e.g., 10 nm or more, and in view of facilitating enhancement of a polishing removal rate, preferably 50 nm or more, and more preferably 100 nm or more, and may be 250 nm or more, or 400 nm or more. The upper limit of the average secondary particle diameter of the abrasive is suitably approximately 10 μm or less in view of sufficiently ensuring the number of the abrasive per unit weight. Furthermore, in view of reducing increase in pad temperature, the average secondary particle diameter is preferably 5 μm or less, more preferably 3 μm or less, and e.g., 1 μm or less. In view of a surface quality after polishing, the average secondary particle diameter of the abrasive in some embodiments may be 600 nm or less, 300 nm or less, 170 nm or less, or 100 nm or less.

The average secondary particle diameter of the abrasive can be measured, for particles having a size of less than 500 nm, as the volume average particle diameter (arithmetic average diameter by volume; Mv) by dynamic light scattering, using, e.g., model “UPA-UT151” manufactured by Nikkiso Co., Ltd. Particles having a size of 500 nm or more can be measured as the volume average particle diameter by an aperture electrical resistance method or the like using model “Multisizer 3” manufactured by Beckman Coulter Inc.

In use of alumina particles (an alumina abrasive) as the abrasive, the alumina particles can be appropriately selected and used from various known alumina particles. Examples of such known alumina particles include α-alumina and intermediate alumina Intermediate alumina herein refers to a collective designation of alumina particles other than α-alumina, and specific examples include γ-alumina, δ-alumina, θ-alumina, η-alumina, κ-alumina, and χ-alumina Alumina referred to as fumed alumina in accordance with classification by production methods (typically, alumina microparticles produced in high-temperature firing of alumina salt) may also be used. Furthermore, alumina referred to as colloidal alumina or alumina sol (e.g., alumina hydrate such as boehmite) is also included in examples of the known alumina particles. In view of processability, it is preferable to contain α-alumina. The alumina abrasive in the art disclosed herein can contain such alumina particles as a single one species or in combination of two or more kinds.

In use of alumina particles as the abrasive, it is generally advantageous that the proportion of the alumina particles in the total abrasive to be used be higher. For example, the proportion of the alumina particles in the total abrasive is preferably 70% by weight or more, more preferably 90% by weight or more, and yet more preferably 95% by weight or more, and may be substantially 100% by weight.

The particle size of the alumina abrasive is not particularly limited, and can be selected so as to exert a desired polishing effect. In view of improving a polishing removal rate, the average primary particle diameter of the alumina abrasive is preferably 50 nm or more, and more preferably 80 nm or more, and may be 150 nm or more, 250 nm or more, or 300 nm or more. The upper limit of the average primary particle diameter of the alumina abrasive is not particularly limited, but is, in view of reducing increase in pad temperature, suitably roughly 5 μm or less. In view of a surface quality after polishing, the upper limit is preferably 3 μm or less, and more preferably 1 μm or less, and may be 750 nm or less, 500 nm or less, 400 nm or less, or 350 nm or less.

In use of alumina particles as an abrasive, the polishing composition disclosed herein may further contain abrasive made of a material other than the alumina described above (hereinafter also referred to as non-alumina abrasive) as far as an effect in the present invention is not impaired. Examples of such a non-alumina abrasive include abrasive substantially formed of any of the following: oxide particles such as silica particles, cerium oxide particles, chromium oxide particles, titanium dioxide particles, zirconium oxide particles, magnesium oxide particles, manganese oxide particles, zinc oxide particles, and iron oxide particles; nitride particles such as silicon nitride particles and boron nitride particles; carbide particles such as silicon carbide particles and boron carbide particles; diamond particles; and carbonates such as calcium carbonate and barium carbonate.

The content of the non-alumina abrasive is suitably, e.g., 30% by weight or less, preferably 20% by weight or less, and more preferably 10% by weight or less in the total weight of the abrasive contained in the polishing composition.

In another preferred embodiment in the art disclosed herein, the polishing composition contains silica particles (a silica abrasive) as the abrasive. The silica abrasive can be appropriately selected and used from various known silica particles. Examples of such known silica particles include colloidal silica and dry silica. In particular, use of colloidal silica is preferable. A silica abrasive containing colloidal silica can preferably achieve a good surface smoothness.

The shape (outer shape) of the silica abrasive may be globular or non-globular. For instance, specific examples of the silica abrasive having non-globular forms include peanut-shaped (i.e., peanut shell-shaped) abrasive, cocoon-shaped abrasive, conpeito-shaped abrasive, and rugby ball-shaped abrasive. In the art disclosed herein, the silica abrasive may take a primary particle form, or a secondary particle form consisting of a plurality of primary particles associating with one another. The silica abrasive may also include a mixture of primary particle forms and secondary particle forms. In a preferred embodiment, at least a part of the silica abrasive is contained in a secondary particle form in the polishing composition.

The silica abrasive to be preferably employed can have an average primary particle diameter of more than 5 nm. In view of a polishing removal rate or the like, the average primary particle diameter of the silica abrasive is preferably 15 nm or more, more preferably 20 nm or more, even more preferably 25 nm or more, and particularly preferably 30 nm or more. The upper limit of the average primary particle diameter of the silica abrasive is not particularly limited, but is suitably roughly 120 nm or less, preferably 100 nm or less, and more preferably 85 nm or less. For example, in view of combining a polishing removal rate and a surface quality at higher levels, preferred are silica abrasive having a BET diameter of 12 nm or more to 80 nm or less, and 15 nm or more to 75 nm or less.

The average secondary particle diameter of the silica abrasive is not particularly limited, but is, in view of a polishing removal rate or the like, preferably 20 nm or more, more preferably 50 nm or more, and yet more preferably 70 nm or more. Furthermore, in view of providing a higher-quality surface, the average secondary particle diameter of the silica abrasive is suitably 500 nm or less, preferably 300 nm or less, more preferably 200 nm or less, yet more preferably 130 nm or less, and particularly preferably 110 nm or less (e.g., 100 nm or less).

The true specific gravity (true density) of the silica particles is preferably 1.5 or more, more preferably 1.6 or more, and even more preferably 1.7 or more. Increase in the true specific gravity of the silica particles leads to tendency to a higher physical ability for polishing. The upper limit of the true specific gravity of the silica particles is not particularly limited, but typically 2.3 or less, e.g., 2.2 or less, 2.0 or less, or 1.9 or less. As the true specific gravity of the silica particles, a measured value can be employed by a liquid displacement method using ethanol as a displacing liquid.

The shape (outer shape) of the silica particles is preferably globular. Without limitation, the average value of the major axis/minor axis ratios of the particles (average aspect ratio) is theoretically 1.00 or more, and may also be e.g., 1.05 or more or 1.10 or more in view of improving a polishing removal rate. Moreover, the average aspect ratio of the particles is suitably 3.0 or less, and may be 2.0 or less. In view of improved smoothness of a surface to be polished, less scratching, etc., the average aspect ratio of the particles is preferably 1.50 or less, and may be 1.30 or less, or 1.20 or less.

The shape (outer shape), average aspect ratio, and the like of the particles can be acquired by, e.g., electron microscopy. A specific procedure for acquiring the average aspect ratio can be, for example, extracting shapes of a predetermined number (e.g., 200) of the particles using a scanning electron microscope (SEM); drawing a minimum rectangle circumscribed to a shape of each of the extracted particles; then calculating, as a major axis/minor axis ratio (aspect ratio), a value by dividing the long side length (major axis value) by the short side length (minor axis value) for the rectangle drawn for the shape of each of the particles; and deriving the average aspect ratio from an arithmetic average of the aspect ratios for the predetermined number of the particles.

In an embodiment where the polishing composition contains a silica abrasive, the polishing composition may further contain an abrasive made of a material other than silica (hereinafter also referred to as a non-silica abrasive). Examples of particles contained in such a non-silica abrasive include particles substantially formed of any of the following: oxide particles such as alumina particles, cerium oxide particles, chromium oxide particles, titanium dioxide particles, zirconium oxide particles, magnesium oxide particles, manganese oxide particles, zinc oxide particles, and iron oxide particles; nitride particles such as silicon nitride particles and boron nitride particles; carbide particles such as silicon carbide particles and boron carbide particles; diamond particles; carbonates such as calcium carbonate and barium carbonate; and the like.

The content of the non-silica abrasive is suitably, e.g., 30% by weight or less, preferably 20% by weight or less, and more preferably 10% by weight or less in the total weight of the abrasive contained in the polishing composition.

The content of the abrasive (e.g., a silica abrasive, an alumina abrasive) in the polishing composition disclosed herein is, in view of reducing increase in pad temperature, suitably less than 5% by weight, advantageously less than 3% by weight, preferably less than 1% by weight, and more preferably less than 0.5% by weight, and may be 0.3% by weight or less, or 0.2% by weight or less. In some embodiments, the content of the abrasive in the polishing composition may be 0.1% by weight or less or less than 0.1% by weight, may be 0.05% by weight or less or less than 0.05% by weight, may be 0.04% by weight or less or less than 0.04% by weight, or may be 0.03% by weight or less or less than 0.03% by weight. The lower limit of the content of the abrasive is not particularly limited, and may be, e.g., 0.000001% by weight or more (i.e., 0.01 ppm or more). In view of enhancing an effect of use of the abrasive, the content of the abrasive in the polishing composition in some embodiments may be 0.00001% by weight or more, 0.0001% by weight or more, 0.001% by weight or more, 0.002% by weight or more, or 0.005% by weight or more. When the polishing composition disclosed herein contains a plurality kinds of abrasives, the content of the abrasive in the polishing composition refers to the total content of the plurality kinds of abrasives.

It is preferable that the polishing composition disclosed herein not substantially contain diamond particles as the particles. Diamond particles have a high hardness and thus can be a factor for limited improvement in smoothness. Diamond particles are also generally expensive and thus not necessarily a beneficial material in terms of cost performance, and there may be less dependence on high-price materials such as diamond particles in terms of practical use. The particles not substantially containing diamond particles, as used herein, means that the proportion of diamond particles in all the particles is 1% by weight or less, more preferably 0.5% by weight or less, and typically 0.1% by weight or less, including a case where the proportion of diamond particles is 0% by weight. In such an embodiment, an application effect of the present invention can be preferably exerted.

In the polishing composition containing the abrasive, a relation between the concentration of oxidant A and the content of the abrasive is not particularly limited, and can appropriately set so as to achieve a desired effect corresponding to a purpose of use, an embodiment of use, etc. The ratio of the concentration of oxidant A Cx [mM] to the content of the abrasive W1 [% by weight], i.e., Cx/W1, can be, e.g., 5 or more, is suitably 50 or more, advantageously 100 or more, and preferably 200 or more. Larger Cx/W1 tends to be accompanied by larger contribution of chemical polishing relative to contribution of mechanical polishing. Such composition can preferably exhibit an effect to reduce increase in pad temperature by combination use of the first metal salt and the second metal salt. In some embodiments, Cx/W1 may be 300 or more, 500 or more, 700 or more, 1000 or more, and furthermore may be 1500 or more, 3000 or more, 5500 or more, or 7500 or more. The upper limit of Cx/W1 is not particularly limited, and in view of preservation stability of the polishing composition, can be, e.g., approximately 100000 or less, and may be 75000 or less, 50000 or less, 20000 or less, 10000 or less, or 9000 or less. In some embodiments, Cx/W1 may be 7000 or less, 5000 or less, or 3000 or less.

Note that in the “Cx/W1” described above, “Cx” represents a numerical value part in indication of the concentration of oxidant A in the polishing composition by a unit “mM”; “W i” refers to a numerical value part in indication of the content of the abrasive in the polishing composition by a unit “% by weight”; and both Cx and W1 are dimensionless numbers.

In the polishing composition containing the abrasive, a relation between the concentration of the first metal salt and the content of the abrasive is not particularly limited, and can appropriately set so as to achieve a desired effect corresponding to a purpose of use, an embodiment of use, etc. The ratio of the concentration of the first metal salt C1 [mM] to the content of the abrasive W1 [% by weight], i.e., C1/W1, can be, e.g., 5 or more, is preferably 10 or more, more preferably 30 or more, and may be 50 or more, or 80 or more. Larger C1/W1 tends to be accompanied by larger contribution of chemical polishing relative to contribution of mechanical polishing. Such composition can preferably exhibit an effect to reduce increase in pad temperature by combination use of the first metal salt and the second metal salt. In some embodiments, C1/W1 may be 100 or more, 150 or more, 200 or more, 300 or more, or 500 or more. The upper limit of C1/W1 is not particularly limited, and in view of preservation stability of the polishing composition, can be, e.g., approximately 5000 or less, and may be 2500 or less, or 1000 or less. In some embodiments, C1/W1 may be 900 or less, 700 or less, or 500 or less.

Note that in the “C1/W1” described above, “C1” represents a numerical value part in indication of the concentration of the first metal salt in the polishing composition by a unit “mM”; “W1” refers to a numerical value part in indication of the content of the abrasive in the polishing composition by a unit “% by weight”; and both C1 and W1 are dimensionless numbers.

In the polishing composition containing the abrasive, a relation between the concentration of the second metal salt and the content of the abrasive is not particularly limited, and can appropriately set so as to achieve a desired effect corresponding to a purpose of use, an embodiment of use, etc. The ratio of the concentration of the second metal salt C2 [mM] to the content of the abrasive W1 [% by weight], i.e., C2/W1, can be, e.g., 5 or more, is preferably 10 or more, more preferably 30 or more, and may be 50 or more, or 80 or more. Larger C2/W1 can preferably exhibit an effect to reduce increase in pad temperature by combination use of the first metal salt and the second metal salt. In some embodiments, C2/W1 may be 150 or more, 300 or more, 500 or more, or 800 or more. The upper limit of C2/W1 is not particularly limited, and in view of preservation stability of the polishing composition, can be, e.g., approximately 10000 or less, and may be 5000 or less, or 2500 or less. In some embodiments, C2/W1 may be 1000 or less, 800 or less, or 600 or less.

Note that in the “C2/W1” described above, “C2” represents a numerical value part in indication of the concentration of the second metal salt in the polishing composition by a unit “mM”; “W1” refers to a numerical value part in indication of the content of the abrasive in the polishing composition by a unit “% by weight”; and both C2 and W1 are dimensionless numbers.

The polishing composition disclosed herein can be preferably implemented even in an embodiment without no abrasive. Such an embodiment better exerts effects to improve a polishing removal rate and to reduce increase in pad temperature by combination use of the first metal salt and the second metal salt.

### (Water)

The polishing composition disclosed herein contains water. As water, ion-exchange water (deionized water), pure water, ultrapure water, distilled water, or the like can be preferably used. The polishing composition disclosed herein may further contain an organic solvent (lower alcohol, lower ketone, or the like) that can be uniformly mixed with water, as necessary. Usually, it is appropriate that 90 vol % or more of the solvent contained in the polishing composition be water, it is preferable that 95 vol % or more thereof be water, and it is more preferable that 99 to 100 vol % thereof be water.

### (Acid)

The polishing composition can contain an acid as necessary, for the purpose of pH adjustment, improvement in a polishing removal rate, and the like. As the acid, both inorganic and organic acids can be used. Examples of the inorganic acids include sulfuric acid, nitric acid, hydrochloric acid, and carbonic acid. Examples of the organic acids include aliphatic carboxylic acids such as formic acid, acetic acid and propionic acid; aromatic carboxylic acids such as benzoic acid and phthalic acid; citric acid; oxalic acid; tartaric acid; malic acid; maleic acid; fumaric acid; succinic acid; organic sulfonic acid; and organic phosphonic acid. These can be used as a single kind or in combination of two or more kinds thereof. When using an acid, the amount to be used is not particularly limited, and can be set according to a purpose of use (e.g., pH adjustment). Alternatively, in some embodiments of the polishing composition disclosed herein, the composition may contain substantially no acid.

### (Basic Compound)

The polishing composition can contain a basic compound as necessary, for the purpose of pH adjustment, improvement in a polishing removal rate, and the like. The basic compound as used herein refers to a compound that has a function to raise pH of the polishing composition by being added to the composition. Examples of the basic compound include alkali metal hydroxides such as potassium hydroxide and sodium hydroxide; carbonates or hydrogencarbonates such as ammonium bicarbonate, ammonium carbonate, potassium bicarbonate, potassium carbonate, sodium bicarbonate, and sodium carbonate; ammonia; quaternary ammonium compounds including quaternary ammonium hydroxides such as tetramethylammonium hydroxide, tetraethylammonium hydroxide, and tetrabutylammonium hydroxide; others, such as amines, phosphates and hydrogen phosphates, and organic acid salts. The basic compound can be used as a single kind or in combination of two or more kinds thereof. In use of the basic compound, the amount to be used is not particularly limited, and can be set according to a purpose of use (e.g., pH adjustment). Alternatively, in some embodiments of the polishing composition disclosed herein, the composition may contain substantially no basic compound.

### (Other Components)

The polishing composition disclosed herein may further contain, as necessary, a known additive that can be used for polishing compositions (e.g., a polishing composition used for polishing a high hardness material such as silicon carbide), such as a chelating agent, a thickener, a dispersant, a surface protective agent, a wetting agent, a surfactant, a corrosion inhibitor, an antiseptic agent, or an antifungal agent, as far as an effect of the present invention is not impaired. Since the content of the additive only has to be appropriately set according to the purpose of addition thereof and does not characterize the present invention, a detailed description thereof will be omitted.

(pH)

The pH of the polishing composition is suitably about 1 to 12. The pH within the range facilitates achievement of a practical polishing removal rate. In some embodiments, the pH may be 12.0 or less, 11.0 or less, 10.0 or less, 9.0 or less, less than 9.0, 8.0 or less, less than 8.0, 7.0 or less, less than 7.0, or 6.0 or less. In view of facilitating more exertion of effects to improve a polishing removal rate and to reduce increase in pad temperature by combination use of the first metal salt and the second metal salt, the pH of the polishing composition in some embodiments is preferably less than 6.0, and may be 5.0 or less, less than 5.0, 4.0 or less, or less than 4.0. The pH may be, e.g., 1.0 or more, 1.5 or more, 2.0 or more, or 2.5 or more.

A method for preparing the polishing composition disclosed herein is not particularly limited. For example, each component to be contained in the polishing composition may be mixed using a well-known mixing device such as a blade stirrer, an ultrasonic disperser, or a homomixer. An embodiment for mixing these components is not particularly limited, and, for example, all components may be mixed at once or in an appropriately set order.

The polishing composition disclosed herein may be a single-agent type or a multi-agent type such as a two-agent type. For example, the polishing composition may be configured to be used for polishing an object to be polished, by mixing of part A, which contains a part of components of the polishing composition (e.g., a component other than water), and part B, which contains the remaining components. These components may be, for example, separated and stored before use, and then mixed in use to prepare the polishing composition in a single liquid. In mixing, dilution water and the like may be further mixed.

### <Object to be Polished>

An object to be polished in the polishing composition disclosed herein is not particularly limited. For example, the polishing composition disclosed herein can be applied to polishing of a substrate having a surface formed of a compound semiconductor material, i.e., a compound semiconductor substrate. A component material of the compound semiconductor substrate is not particularly limited, and examples thereof can include group II-VI compound semiconductors such as cadmium telluride, zinc selenide, cadmium sulfide, mercury cadmium telluride, and cadmium zinc telluride; group III-V compound semiconductors such as gallium nitride, gallium arsenide, gallium phosphide, indium phosphide, aluminum gallium arsenide, gallium indium arsenide, indium gallium arsenide nitride, aluminum gallium indium phosphide; IV-IV group compound semiconductors such as silicon carbide and germanium silicide. A plurality of the materials listed above may form an object to be polished. In a preferred embodiment, the polishing composition disclosed herein can be applied to polishing of a substrate having a surface formed of a chemical semiconductor material other than oxides (i.e., a non-oxide). Polishing of a substrate having a surface formed of a non-oxide chemical semiconductor material is likely to lead to preferable exertion of an effect to promote polishing by an oxidant contained in the polishing composition disclosed herein.

The polishing composition disclosed herein can be preferably used for polishing e.g., a surface of an object to be polished having a Vickers hardness of 500 Hv or more. Such a Vickers hardness is preferably 700 Hv or more, e.g., 1000 Hv or more or 1500 Hv or more. The Vickers hardness of a material to be polished may be 1800 Hv or more, 2000 Hv or more, or 2200 Hv or more. The upper limit of the Vickers hardness of an object to be polished is not particularly limited, and may be e.g., approximately 7000 Hv or less, 5000 Hv or less, or 3000 Hv or less. Herein the Vickers hardness can be measured in accordance with JIS R 1610: 2003. The international standard corresponding to this standard in JIS is ISO 14705: 2000.

Examples of the material having a Vickers hardness of 1500 Hv or more include silicon carbide, silicon nitride, titanium nitride, and gallium nitride. An object to be polished in the art disclosed herein may have a monocrystalline surface of such a material with mechanical and chemical stability. In particular, a surface of an object to be polished is preferably formed of either of silicon carbide or gallium nitride, and more preferably formed of silicon carbide. Silicon carbide has been expected as a compound semiconductor substrate material having less power loss and good heat resistance, etc., and thus there is a particularly large practical advantage of improvement of productivity by increasing a polishing removal rate. The art disclosed herein can be particularly preferably applied to polishing of a monocrystalline surface of silicon carbide.

### <Polishing Method>

The polishing composition disclosed herein can be used for polishing an object to be polished in an exemplary embodiment including the following operations.

That is, a polishing slurry (slurry) containing any of the polishing compositions disclosed herein is prepared. Preparation of the polishing slurry may include preparing the polishing slurry by subjecting the polishing composition to operations such as concentration adjustment (e.g., dilution) and pH adjustment. Alternatively, the polishing composition may be directly used as a polishing slurry. In use of a multi-agent type polishing composition, preparation of the polishing slurry may include mixing the agents thereof, diluting one or more of the agents before the mixing, diluting the resulting mixture after the mixing, and the like.

Next, the polishing slurry is supplied to an object to be polished, and subjected to polishing by a common method performed by those skilled in the art. For example, one method is to set an object to be polished in a common polishing machine and supply the polishing slurry to a surface to be polished of the object to be polished through a polishing pad of the polishing machine. Typically, while supplying the polishing slurry continuously, the polishing pad is pressed against the surface to be polished of the object to be polished, and both of the surface and the pad are moved (e.g., rotated) relative to each other. Polishing of the object to be polished is completed through such a polishing step.

Note that the aforementioned content and content ratio for each component that can be contained in the polishing composition in the art disclosed herein typically means the content and content ratio in the polishing composition in practical supply to an object to be polished (i.e., at a point of use), and therefore can be translated as the content and content ratio in the polishing slurry.

The description provides a polishing method for polishing an object to be polished (typically, a material to be polished) and a method for producing a polished object using the polishing method. The polishing method is characterized by including a step of polishing an object to be polished using the polishing composition disclosed herein. A polishing method according to one preferred embodiment includes a step of performing preliminary polishing (preliminary polishing step) and a step of performing final polishing (final polishing step). In one typical embodiment, the preliminary polishing step is a polishing step set immediately before the final polishing step. The preliminary polishing step may be a single-step polishing step or a polishing step including two or more sub-steps. The final polishing step as referred to herein designates a step of applying final polishing to an object to be polished that experienced preliminary polishing, specifically, a polishing step set at the end (i.e., on the most downstream) of polishing steps performed with a polishing slurry containing an abrasive. In such a polishing method including the preliminary polishing step and the final polishing step, the polishing composition disclosed herein may be used in the preliminary polishing step, may be used in the final polishing step, or may be used in both of the preliminary polishing step and the final polishing step.

The preliminary polishing and the final polishing can be applied to polishing using either a single-side polishing machine or a double-side polishing machine. In a single-side polishing machine, one side of an object to be polished is polished by attaching the object to be polished to a ceramic plate with wax, holding the object to be polished with a holder called a carrier, and then pressing a polishing pad against one side of the object to be polished and moving both relative to each other with supplying a polishing composition. This movement is, e.g., rotational movement. In a double-side polishing machine, both sides of an object to be polished are polished simultaneously by holding the object to be polished with a holder called a carrier, and then pressing polishing pads against opposing sides of the object to be polished and rotating them relative to one another with supplying a polishing composition from above.

Conditions of the polishing described above is appropriately set based on the kind of a material to be polished, surface properties of interest (specifically, smoothness), a polishing removal rate and the like, and thus is not limited to particular conditions. For example, with regard to processing pressure, the polishing composition disclosed herein can be used within a wide pressure range such as 10 kPa or more to 150 kPa or less. In view of preferably combining a high polishing removal rate and reduction of increase in pad temperature, the processing pressure in some embodiments may be, e.g., 20 kPa or more, 30 kPa or more, or 40 kPa or more, and can also be 100 kPa or less, 80 kPa or less, or 60 kPa or less. The polishing composition disclosed herein can also be preferably used in polishing under processing conditions, e.g., with 30 kPa or more or higher, thereby allowing enhancing productivity of a target product derived via the polishing (a polished object). The processing pressure referred to herein is synonymous with polishing pressure.

The polishing pad used in each polishing step disclosed herein is not particularly limited. For example, any of a non-woven fabric type, a suede type, and a hard foamed polyurethane type may be used. In some embodiments, a non-woven fabric type polishing pad may be preferably employed. In an embodiment using the polishing pad described above, an effect to reduce increase in pad temperature, which is an effect provided by the art disclosed herein, is preferably exerted. The polishing pad used in the art disclosed herein is an abrasive-free polishing pad.

An object to be polished that is polished by the method disclosed herein is typically cleaned after polishing. The cleaning can be performed using a suitable cleaning solution. The cleaning solution to be used is not particularly limited, and a known or conventional cleaning solution can be appropriately selected and used.

The polishing method disclosed herein may include any other step in addition to the preliminary polishing step and final polishing step described above. Examples of such a step include a mechanical polishing step, and a lapping step performed before the preliminary polishing step. In the mechanical polishing step, an object to be polished is polished with a liquid of diamond abrasive dispersed in a solvent. In some preferred embodiments, the dispersion contains no oxidant. The lapping step is a step of polishing with pressing a surface of a polishing platen, such as a cast iron platen, to an object to be polished. Therefore, in the lapping step, no polishing pad is used. The lapping step is typically performed by supplying abrasive between a polishing platen and an object to be polished. The abrasive is typically a diamond abrasive. In addition, the polishing method disclosed herein may include an additional step before the preliminary polishing step or between the preliminary polishing step and the final polishing step. The additional step is, for example, a cleaning step or a polishing step.

### <Production Method of Polished Object>

The art disclosed herein may include provision of a method for producing a polished object that includes a polishing step with use of any of the polishing methods described above and a polished object produced by the method. The production method of the polished object is, for example, a method for producing a silicon carbide substrate. That is, the art disclosed herein provides a method for producing a polished object that includes polishing an object to be polished having a surface made of a high hardness material by applying any of the polishing methods disclosed herein, and provides a polished object produced by the method. The production method described above can efficiently provide a substrate produced via polishing, such as a silicon carbide substrate.

### EXAMPLES

Several examples relating to the present invention will be described below, but the present invention is not intended to be limited to embodiments shown in the examples. In the following description, “%” is on a weight basis unless otherwise specified.

### Experimental Example 1

### Preparation of Polishing Composition

### Example A1

An alumina abrasive, potassium permanganate as oxidant A, calcium nitrate as the first metal salt, aluminum nitrate as the second metal salt, and deionized water were mixed to prepare a polishing composition containing each component with the following concentration: 0.1% alumina abrasive, 181 mM potassium permanganate (calculated based on Mn), 9.52 mM calcium nitrate (calculated based on Ca), and 9.52 mM aluminum nitrate (calculated based on Al).

### Comparative Example A1

An alumina abrasive, potassium permanganate as oxidant A, calcium nitrate, and deionized water were mixed to prepare a polishing composition containing each component with the following concentration: 0.1% alumina abrasive, 181 mM potassium permanganate (calculated based on Mn), and 9.52 mM calcium nitrate (calculated based on Ca).

### Comparative Example A2

An alumina abrasive, potassium permanganate as oxidant A, aluminum nitrate, and deionized water were mixed to prepare a polishing composition containing each component with the following concentration: 0.1% alumina abrasive, 181 mM potassium permanganate (calculated based on Mn), 9.52 mM aluminum nitrate (calculated based on Al).

In the polishing compositions in Example A1, Comparative Example A1 and Comparative Example A2, an α-alumina abrasive with an average primary particle diameter of 310 nm were used as the alumina abrasive. Each polishing composition according to a corresponding example was adjusted to pH 2.5 using nitric acid.

### <Polishing of Object to be Polished>

A SiC wafer was preliminarily polished using a preliminary polishing composition including an alumina abrasive. The preliminarily polished SiC wafer was set as an object to be polished, and polished under the following polishing conditions using each polishing composition according to a corresponding example as a polishing slurry.

### [Polishing Conditions]

Polishing machine: model “RDP-500”, manufactured by Fujikoshi Machinery Corp.

Polishing pad: “SUBA800XY” (non-woven fabric type), manufactured by Nitta Haas Incorporated.

Processing pressure: 44.1 kPa.

Platen rotational speed: 120 revolutions/min.

Head rotational speed: 120 revolutions/min.

Supply rate of polishing slurry: 20 mL/min.

Method of using polishing slimy: one-way.

Polishing time: 15 mins.

Object to be polished: 4 inch SiC wafer (conduction type: n-type, crystalline type: 4H-SiC, off angle to the C-axis of the main surface (0001):4°), 1 sheet/batch.

Temperature of polishing slurry: 23° C.

### <Measurement and Evaluation>

### (Polishing Removal Rate)

After the SiC wafer was polished under the aforementioned polishing condition using each polishing composition of a corresponding example, a polishing removal rate was calculated according to the following calculation formulae (1) and (2):

polishing allowance [cm]=difference between weight of SiC wafer before and after polishing [g]/density of SiC [g/cm³](=3.21 g/cm³)/area to be polished [cm²](=78.54 cm²) (1)

polishing removal rate [nm/h]=polishing allowance [cm]×10⁷/polishing time (=15/60 hours). (2)

The polishing removal rate thus obtained was converted to a relative value to that in Comparative Example A1 as 100%. On the basis of the relative value, the polishing removal rate was evaluated according to the following five grades and shown in Table 1. Grade A means that a polishing removal rate is increased more than 1.15 times to 1.5 times relative to Comparative Example A1.

AA: more than 150% to 200% or less.

A: more than 115% to 150% or less.

B: 85% or more to 115% or less.

C: 50% or more to less than 85%.

D: less than 50%.

### (Pad Temperature)

Temperature of a polishing pad during polishing under the aforementioned polishing conditions was measured. In measuring the pad temperature, a template using a backing material made of a suede material was used as a wafer support part, and attached so as to provide the wafer with a projection length of 100 μm or more. In polishing, the wafer was kept so as to attach to the suede material with water. As the pad temperature, an output value from a pad temperature measurement device (infrared thermal emission thermometer) mounted on the polishing machine was employed directly. Measurement was performed for 10 to 15 minutes after start of polishing, and the average temperature during that span was defined as pad temperature during polishing with each polishing composition according to a corresponding example.

The result thus obtained was substituted into the following formula: ΔT [° C.]=(pad temperature in Comparative Example A1)−(pad temperature in each example); on the basis of the ΔT (i.e., reduction in pad temperature relative to pad temperature in Comparative Example A1), an effect to reduce increase in pad was evaluated according to the following five grades and shown in Table 1. Having a ΔT of 0° C. or less (grade D) means that pad temperature is the same as or higher than that in Comparative Example A1.

AA: having a ΔT of 2.5° C. or more.

A: having a ΔT of 2.0° C. or more to less than 2.5° C.

B: having a ΔT of 1.2° C. or more to less than 2.0° C.

C: having a ΔT of more than 0° C. to less than 1.2° C.

D: having a ΔT of 0° C. or less.

As Comparative Example A0, a polishing composition having composition with no calcium nitrate in Comparative Example A1 was prepared, and measured and evaluated for a polishing removal rate and pad temperature in the same manner. The results showed that the polishing removal rate in Comparative Example A1 was about 1.2 times of that in Comparative Example A0, and that the pad temperature in Comparative Example A1 was higher by 1.1° C. than that in Comparative Example A0. That is, Comparative Example A1 exhibited not only improvement in a polishing removal rate but also increase in pad temperature compared to Comparative Example A0.

TABLE 1

| | First metal salt | | Second metal salt | | Polishing | Reduction of |
|---|---|---|---|---|---|---|
| | | Concentration | | Concentration | removal | increase in pad |
| | Species | [mM] | Species | [mM] | rate | temperature |
| Comparative | — | — | — | — | C | C |
| Example A0 | | | | | | |
| Comparative | calcium | 9.52 | — | — | B | D |
| Example A1 | nitrate | | | | | |
| Comparative | — | — | aluminum | 9.52 | A | B |
| Example A2 | | | nitrate | | | |
| Example A 1 | calcium | 9.52 | aluminum | 9.52 | A | AA |
| | nitrate | | nitrate | | | |

As shown in Table 1, the polishing composition in Example A1 containing a combination of calcium nitrate as a first metal salt and aluminum nitrate as a second metal salt enabled more improvement in a polishing removal rate as well as significant reduction in pad temperature compared to the polishing composition in Comparative Example A1.

### Experimental Example 2

### Preparation of Polishing Composition

### Example B1

Potassium permanganate as oxidant A, calcium nitrate as the first metal salt, aluminum nitrate as the second metal salt, and deionized water were mixed to prepare a polishing composition containing each component with the following concentration: 105 mM potassium permanganate (calculated based on Mn), 7.6 mM calcium nitrate (calculated based on Ca), 38 mM aluminum nitrate (calculated based on Al), and no abrasive.

### Comparative Example B1

Potassium permanganate as oxidant A, calcium nitrate, and deionized water were mixed to prepare a polishing composition containing each component with the following concentration: 105 mM potassium permanganate (calculated based on Mn), 3.8 mM calcium nitrate (calculated based on Ca), and no abrasive.

The polishing compositions in Example B1 and Comparative Example B1 had a pH of 3.4-3.5.

### <Polishing of Object to be Polished>

A SiC wafer was preliminarily polished using a preliminary polishing composition including an alumina abrasive. The preliminarily polished SiC wafer was set as an object to be polished, and polished under the following polishing conditions using each polishing composition according to a corresponding example as a polishing slurry.

### [Polishing Conditions]

Polishing machine: model “RDP-500”, manufactured by Fujikoshi Machinery Corp.

Polishing pad: “SUBA800XY” (non-woven fabric type), manufactured by Nitta Haas Incorporated.

Processing pressure: 29.4 kPa.

Platen rotational speed: 100 revolutions/min.

Head rotational speed: 100 revolutions/min.

Supply rate of polishing slurry: 20 mL/min.

Method of using polishing shiny: one-way.

Polishing time: 1 hour.

Object to be polished: 2 inch SiC wafer (conduction type: n-type, crystalline type: 4H-SiC, off angle to the C-axis of the main surface (0001):4°), 1 sheet/batch.

Temperature of polishing slurry: 23° C.

### <Measurement and Evaluation>

### (Polishing Removal Rate)

After the SiC wafer was polished under the aforementioned polishing condition using each polishing composition of a corresponding example, a polishing removal rate was calculated according to the following calculation formulae (1) and (2):

polishing allowance [cm]=difference between weight of SiC wafer before and after polishing [g]/density of SiC [g/cm³](=3.21 g/cm³)/area to be polished [cm²](=19.62 cm²) (1)

polishing removal rate [nm/h]=polishing allowance [cm]×10⁷/polishing time (=1 hour). (2)

The polishing removal rate thus obtained was converted to a relative value to that in Comparative Example B1 as 100%. On the basis of the relative value, the polishing removal rate was evaluated according to the following five grades and shown in Table 2. Grade AA means that a polishing removal rate is increased more than 1.5 times to twice relative to Comparative Example B1.
AA: more than 150% to 200% or less
A: more than 115% to 150% or less
B: 85% or more to 115% or less
C: 50% or more to less than 85%
D: less than 50%

Temperature of a polishing pad during polishing under the aforementioned polishing conditions was measured using a pad temperature measurement device (infrared thermal emission thermometer) mounted on the polishing machine Measurement was performed in the same manner as Experimental Example 1, except for providing the wafer with a projection length of 200 μm or more, and defining the average temperature over a period from 5 to 55 minutes after start of polishing as pad temperature during polishing with each polishing composition according to a corresponding example.

The result thus obtained was substituted into the following formula: ΔT [° C.]=(pad temperature in Comparative Example B1)−(pad temperature in each example); on the basis of the ΔT (i.e., reduction in pad temperature relative to pad temperature in Comparative Example B1), an effect to reduce increase in pad was evaluated according to the following five grades and shown in Table 2. Having a ΔT of 0° C. or less (grade D) means that pad temperature is the same as or higher than that in Comparative Example B1.
AA: having a ΔT of 2.5° C. or more.
A: having a ΔT of 2.0° C. or more to less than 2.5° C.
B: having a ΔT of 1.2° C. or more to less than 2.0° C.
C: having a ΔT of more than 0° C. to less than 1.2° C.
D: having a ΔT of 0° C. or less.

As Comparative Example B0, a polishing composition having composition with no calcium nitrate in Comparative Example B1 was prepared, and measured and evaluated for a polishing removal rate and pad temperature in the same manner. The results showed that the polishing removal rate in Comparative Example B1 was about 3 times of that in Comparative Example B0, and that the pad temperature in Comparative Example B1 was higher by 1° C. than that in Comparative Example B0. That is, Comparative Example B1 exhibited not only improvement in a polishing removal rate but also increase in pad temperature compared to Comparative Example B0.

TABLE 2

| | First metal salt | | Second metal salt | | Polishing | Reduction of |
|---|---|---|---|---|---|---|
| | | Concentration | | Concentration | removal | increase in pad |
| | Species | [mM] | Species | [mM] | rate | temperature |
| Comparative | — | — | — | — | D | C |
| Example B0 | | | | | | |
| Comparative | calcium | 3.8 | — | — | B | D |
| Example B1 | nitrate | | | | | |
| Example B1 | calcium | 7.6 | aluminum | 38 | AA | AA |
| | nitrate | | nitrate | | | |

As shown in Table 2, the polishing composition in Example B1 containing a combination of calcium nitrate as a first metal salt and aluminum nitrate as a second metal salt enabled more improvement in a polishing removal rate as well as significant reduction in pad temperature compared to the polishing composition in Comparative Example B1. Furthermore, as Example B2, a polishing composition having composition with substitution of aluminum nitrate in the polishing composition in Example B1 with aluminum chloride having the same concentration (calculated based on Al) was prepared, and measured and evaluated in the same manner. The results showed an effect to reduce pad temperature compared to Comparative Example B1 as in the case of Example B1, and provided a polishing removal rate comparable with Example B1. Comparing Example B1 and Example B2, Example B1, which had the same anion species in the first metal salt and the second metal salt, exhibited larger reduction in pad temperature.

### Preparation of Experimental Example 3

### Preparation of Polishing Composition

### Example C1

A silica abrasive, potassium permanganate as oxidant A, calcium nitrate as the first metal salt, aluminum nitrate as the second metal salt, and deionized water were mixed to prepare a polishing composition containing each component with the following concentration: 0.1% silica abrasive, 189.8 mM potassium permanganate (calculated based on Mn), 10 mM calcium nitrate (calculated based on Ca), and 30 mM aluminum nitrate (calculated based on Al).

### Comparative Example C1

A silica abrasive, potassium permanganate as oxidant A, calcium nitrate, and deionized water were mixed to prepare a polishing composition containing each component with the following concentration: 0.1% silica abrasive, 189.8 mM potassium permanganate (calculated based on Mn), and 10 mM calcium nitrate (calculated based on Ca).

### Comparative Example C2

A silica abrasive, potassium permanganate as oxidant A, aluminum nitrate, and deionized water were mixed to prepare a polishing composition containing each component with the following concentration: 0.1% silica abrasive, 189.8 mM potassium permanganate (calculated based on Mn), and 30 mM aluminum nitrate (calculated based on Al).

In the polishing compositions in Example C1, Comparative Example C1 and Comparative Example C2, colloidal silica with an average primary particle diameter of 35 nm were used as the silica abrasive. Each polishing composition according to a corresponding example was adjusted to pH 3.0 using nitric acid.

### <Polishing of Object to be Polished>

A SiC wafer was preliminarily polished using a preliminary polishing composition including an alumina abrasive. The preliminarily polished SiC wafer was set as an object to be polished, and polished under the following polishing conditions using each polishing composition according to a corresponding example as a polishing slurry.

### [Polishing Conditions]

Polishing machine: model “RDP-500”, manufactured by Fujikoshi Machinery Corp.

Polishing pad: “SUBA800XY” (non-woven fabric type), manufactured by Nitta Haas Incorporated.

Processing pressure: 44.1 kPa.

Platen rotational speed: 120 revolutions/min.

Head rotational speed: 120 revolutions/min.

Supply rate of polishing slurry: 20 mL/min.

Method of using polishing slimy: one-way.

Polishing time: 15 mins.

Object to be polished: 4 inch SiC wafer (conduction type: n-type, crystalline type: 4H-SiC, off angle to the C-axis of the main surface (0001):4°), 1 sheet/batch.

Temperature of polishing slurry: 23° C.

### <Measurement and Evaluation>

### (Polishing Removal Rate)

After the SiC wafer was polished under the aforementioned polishing condition using each polishing composition of a corresponding example, a polishing removal rate was calculated according to the following calculation formulae (1) and (2):

polishing allowance [cm]=difference between weight of SiC wafer before and after polishing [g]/density of SiC [g/cm³](=3.21 g/cm³)/area to be polished [cm²](=78.54 cm²) (1)

polishing removal rate [nm/h]=polishing allowance [cm]×10⁷/polishing time (=1 hour). (2)

The polishing removal rate thus obtained was converted to a relative value to that in Comparative Example C1 as 100%. On the basis of the relative value, the polishing removal rate was evaluated according to the following five grades and shown in Table 3. Grade AA means that a polishing removal rate is increased more than 1.5 times relative to Comparative Example C1.
AA: more than 150%
A: more than 115% to 150% or less
B: 85% or more to 115% or less
C: 50% or more to less than 85%
D: less than 50%

### (Pad Temperature)

Temperature of a polishing pad during polishing under the aforementioned polishing conditions was measured using a pad temperature measurement device (infrared thermal emission thermometer) mounted on the polishing machine Measurement was performed in the same manner as Experimental Example 1, except for providing the wafer with a projection length of 200 μm or more, and defining the average temperature over a period from 5 to 55 minutes after start of polishing as pad temperature during polishing with each polishing composition according to a corresponding example.

The result thus obtained was substituted into the following formula: ΔT [° C.]=(pad temperature in Comparative Example C1)−(pad temperature in each example); on the basis of the ΔT (i.e., reduction in pad temperature relative to pad temperature in Comparative Example C1), an effect to reduce increase in pad was evaluated according to the following five grades and shown in Table 3. Having a ΔT of 0° C. or less (grade D) means that pad temperature is the same as or higher than that in Comparative Example C1.
AA: having a ΔT of 2.5° C. or more.
A: having a ΔT of 2.0° C. or more to less than 2.5° C.
B: having a ΔT of 1.2° C. or more to less than 2.0° C.
C: having a ΔT of more than 0° C. to less than 1.2° C.
D: having a ΔT of 0° C. or less.

As Comparative Example C0, a polishing composition having composition with no calcium nitrate in Comparative Example C1 was prepared, and measured and evaluated for a polishing removal rate and pad temperature in the same manner. The results showed that the polishing removal rate in Comparative Example C1 was about 1.2 times of that in Comparative Example C0, and that the pad temperature in Comparative Example C1 was higher by 1° C. than that in Comparative Example C0. That is, Comparative Example C1 exhibited not only improvement in a polishing removal rate but also increase in pad temperature compared to Comparative Example C0.

TABLE 3

| | First metal salt | | Second metal salt | | Polishing | Reduction of |
|---|---|---|---|---|---|---|
| | | Concentration | | Concentration | removal | increase in pad |
| | Species | [mM] | Species | [mM] | rate | temperature |
| Comparative | — | — | — | — | C | C |
| Example C0 | | | | | | |
| Comparative | calcium | 10 | — | — | B | D |
| Example C1 | nitrate | | | | | |
| Comparative | — | — | aluminum | 30 | AA | B |
| Example C2 | | | nitrate | | | |
| Example C1 | calcium | 10 | aluminum | 30 | AA | AA |
| | nitrate | | nitrate | | | |

As shown in Table 3, the polishing composition in Example C1 containing a combination of calcium nitrate as a first metal salt and aluminum nitrate as a second metal salt enabled more improvement in a polishing removal rate as well as significant reduction in pad temperature compared to the polishing composition in Comparative Example C1. Furthermore, as Example C2, a polishing composition having composition with substitution of aluminum nitrate in the polishing composition in Example C1 with aluminum chloride having the same concentration (calculated based on Al) was prepared, and measured and evaluated in the same manner. The results showed an effect to reduce pad temperature compared to Comparative Example C1 as in the case of Example C1, and provided a polishing removal rate comparable with Example C1. Comparing Example C1 and Example C2, Example C1, which had the same anion species in the first metal salt and the second metal salt, exhibited larger reduction in pad temperature.

While specific examples of the present invention have been described above in detail, these are only illustrative, and do not limit the scope of the claims. The technologies recited in the claims include various modifications and alternations of the specific examples illustrated above.

1. A polishing composition comprising:
water;
an oxidant A selected from compounds other than peroxide;
a first metal salt selected from alkaline-earth metal salts; and
a second metal salt selected from salts each of which has a cation of a metal belonging to groups 3 to 16 in the periodic table and an anion.

2. The polishing composition according to claim 1, wherein the oxidant A is permanganate.

3. The polishing composition according to claim 1, wherein the first metal salt is nitrate.

4. The polishing composition according to claim 1, wherein the second metal salt is aluminum salt.

5. The polishing composition according to claim 1, wherein the first metal salt and the second metal salt have the same anion species.

6. The polishing composition according to claim 1, wherein a ratio of the concentration of the second metal salt [mM] to the concentration of the first metal salt [mM] is 0.1 to 10.

7. The polishing composition according to claim 1, further comprising an abrasive.

8. The polishing composition according to claim 1, wherein the polishing composition in use for polishing a material having a Vickers hardness of 1500 Hv or more.

9. The polishing composition according to claim 1, wherein the polishing composition in use for polishing silicon carbide.

10. A polishing method comprising polishing an object to be polished using the polishing composition according to claim 1.

11. The polishing composition according to claim 7, wherein the abrasive is formed of alumina particles.

12. The polishing composition according to claim 7, wherein the abrasive is formed of silica particles.

13. The polishing composition according to claim 7, wherein a ratio of the concentration of the oxidant A [mM] to the content of the abrasive [% by weight] is 5 or more 100000 or less.

14. The polishing composition according to claim 1, wherein the concentration of the second metal salt in the polishing composition is 0.1 mM or more 250 mM or less.

15. The polishing composition according to claim 1, wherein a ratio of the concentration of the second metal salt [mM] to the concentration of oxidant A [mM] is 0.0002 or more 200 or less.

16. The polishing composition according to claim 1, wherein a ratio of the concentration of the second metal salt [mM] to the content of the abrasive [% by weight] is 150 or more 10000 or less.

17. A polishing composition consisting essentially of:
water;
an oxidant A selected from compounds other than peroxide;
a first metal salt selected from alkaline-earth metal salts; and
a second metal salt selected from salts each of which has a cation of a metal belonging to groups 3 to 16 in the periodic table and an anion.

18. A polishing composition comprising:
water;
permanganate;
calcium nitrate; and
aluminum nitrate.
